(19) United States
(12) Patent Application Publication
(10) Pub. No.: US 2005/0212016 A1
(43) Pub. Date: Sep. 29, 2005

(54) On-chip integrated detector for analyzing fluids

(75) Inventors: Karl Brunner, Hallbergmoos (DE); Gerhard Abstreiter, Kirchdorf (DE); Marc Tornow, Munchen (DE); Sanjiv Sharma, Munchen (DE)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/086,235

(22) Filed: Mar. 23, 2005

(30) Foreign Application Priority Data
Mar. 23, 2004 (DE) 10 2004 014 537.7

(51) Int. Cl. H01L 23/58

(52) U.S. Cl. 257/253

(57) ABSTRACT

On-chip integrated detector for analyzing fluids, comprising insulating material partly enclosing a cavity for accommodating an analyte, said cavity being defined at the bottom and at least partly at its sides by said insulating material, and a gateless field effect transistor (FET) formed in a distance from the bottom of the cavity, the sensing surface of which is facing the analyte.

The invention relates to on-chip integrated detectors for analyzing fluids.

The International Application WO 00/51180 discloses an silicon-on-insulator sensor having a silicon oxide sensing surface. Drain and source of a FET are formed on one side of a silicon oxide layer forming the substrate, and the other side of the silicon oxide layer is brought in contact with the analyte.

The patent publication DE 102 21 799 A1 discloses a local silicon-on-insulator biosensor with a flat surface being used for adsorption based sensing. Biofunctionalized structures of the surface are use for local biosensing.

It is an object of the present invention to provide highly sensitive, miniaturized biosensor chip for analyzing fluids.

This object is achieved by a Biosensor chip for analyzing fluids, comprising insulating material partly enclosing a cavity for accommodating an analyte, said cavity being defined at the bottom and at least partly at its sides by said insulating material, and a gateless field effect transistor (FET) formed in a distance from the bottom of the cavity, the sensing surface of which is facing the analyte.

When the analyte fluid is introduced in said cavity, the sensing surface the channel of the FET is influenced by the fluid. The change in the current flowing or Resistance through the FET before the fluid influences the channel of the FET and when the fluid influences the channel of the FET is then evaluated for analyzing the fluid.

This biosensor chip has a minimum size because the FET is part of the housing or of the walls of the cavity which accommodates the analyte.

According to a preferred embodiment of the invention, the cavity is formed as a channel.

According to one embodiment the cavity has an opening which is substantially opposed to the bottom side.

The material defining the bottom of the cavity can consist of Si and it may have a passivation layer on it. The material defining the bottom side of the cavity and the buried layer material defining further part of the cavity may consist of SiO₂. The FET is preferably formed in the top silicon flat layer.

There can be one or plural FETS partly extend over the opening of the cavity. The one or plural FETs can bridge the opening. This embodiment is especially advantageous when the cavity has the form of a channel. The FET or FETs can be arranged such that the sensing area(s) of the channel(s) of the FET(s) bridge the opening.

According to a further embodiment there also can be a gate electrode is provided for biasing the gate of the FET. In this case, too, the analyte is the gate of the FET. The additional gate electrode rather serves to bias the channel of the FET by a fixed amount in order to adjust the working range of the FET.

A thin positive passivating layer can be sputtered or grown on the sensing area(s) of the FET(s). This passivating layer also serves as a protection against corrosion of the sensing area.

According to a preferred embodiment of the invention, channel like cavity has an inlet opening and an outlet opening. There may be provided an inlet reservoir and a waste reservoir for the channel like cavity.

This preferred embodiment is a novel FET design integrated with micro-fluidic structures. It is a new combination of a micro-fluidic system and a detector system, all integrated on one platform, namely on one chip.

With this embodiment a removable cover plate can be provided for covering any further open part of the channel like cavity. The removable cover plate can have openings for accessing the main reservoir and the waste reservoir.

According to a further development of the invention the channel like cavity has a meander like form. This development yields the advantage that a relative long channel can be achieved on a small chip. This can be of advantage when travelling length is used to separate components contained in the analyte.

According to the invention pumping means are provided for conveying analyte from the main reservoir to the waste reservoir.

According to another development of the invention electrokinetic means are provided for conveying analyte through the channel like cavity. Such electrokinetic means can comprise an electrical means for applying a voltage across part or all the length of the channel like cavity.

In operation, the charged analytes and the medium, more specifically the buffer solution (electrolyte medium held on a specific electrical potential) and the charged species, passing laterally or underneath the doped and preferably passivated top silicon layer act as the gate electrode.

According to another embodiment of the invention inlet opening of and/or channels or channels of the biosensor are deliberately constructed to enhance turbulent flows to facilitate mixing of the analyte itself or of the analyte and buffer solution.

According to another preferred embodiment of the invention, there is a second channel like cavity oriented substantially rectangular to the main channel like cavity and communicating with it at a crossing point. Each channel like cavity communicates with a main or inlet reservoir and with a waste reservoir.

This further development makes yields a lab-on-chip.

The inlet reservoir of one of the channel like cavities can accommodate the analyte and the other inlet reservoir can accommodate a buffer solution. Both fluids are mixed at the crossing point and thereby electrophoretic migration can be controlled and detected in the main channel like cavity downstream of the crossing point.

Again, an additional gate electrode can be provided for biasing the channel of the FET.

According to a still further embodiment of the invention, from a main channel like cavity a number of branch channels is branched off and there is at least one means for measuring the electric charge of the fluid in a region of each branch channel in a distance from the main channel like cavity.

This is a different lab-on-chip which is especially apt for analyzing proteins.

Preferably there are electrical means for variably applying a bias voltage across the length or part of the length of the branch channels. The electrical means can bias the branch channels to prevent movement of the fluids from the main channel like cavity into the branch channels.

The electrical means can bias the branch channels to promote movement of the fluids from the main channel like cavity to the distant end of the branch channels.

The measuring means can be FETs which can be crossing the branch channels. Preferably the channels of the FETs are bridging the branch channels.

There can be plural measuring means at each branch channel.

The invention will now be described by way of example and with reference to the accompanying drawings in which:

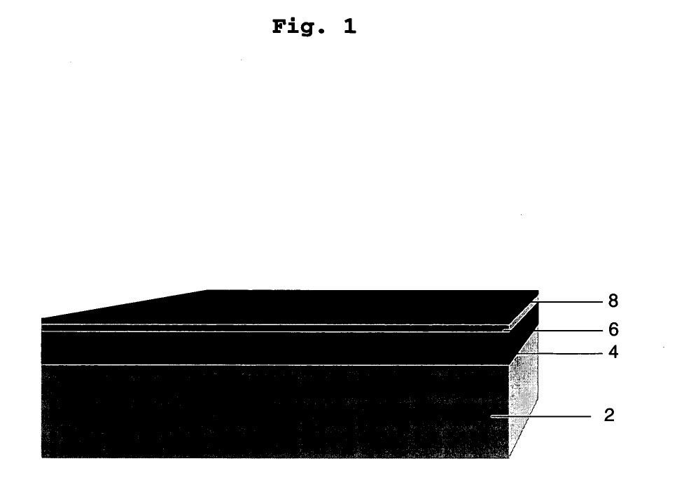

FIG. 1 shows a multi-layer SOI substrate,

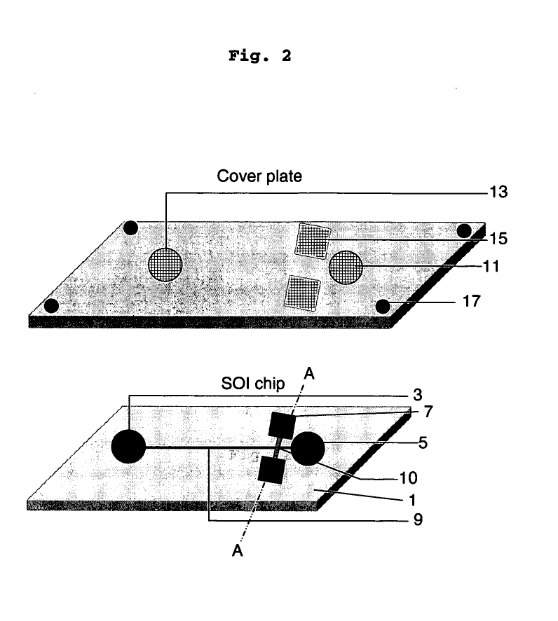

FIG. 2 shows a sensor chip along with the cover plate,

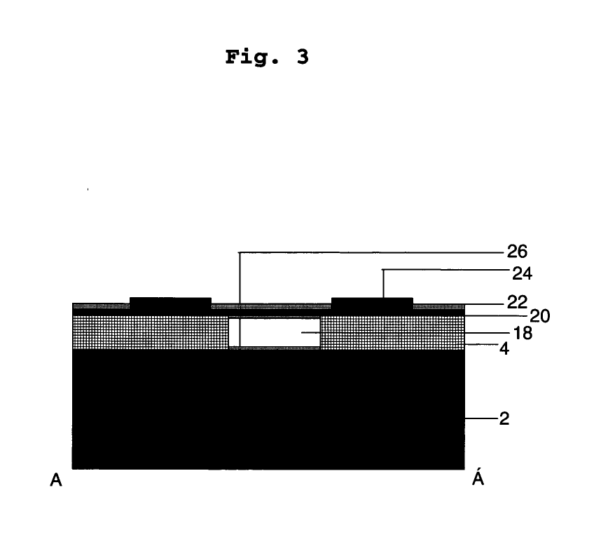

FIG. 3 shows a cross sectional view of the sensor,

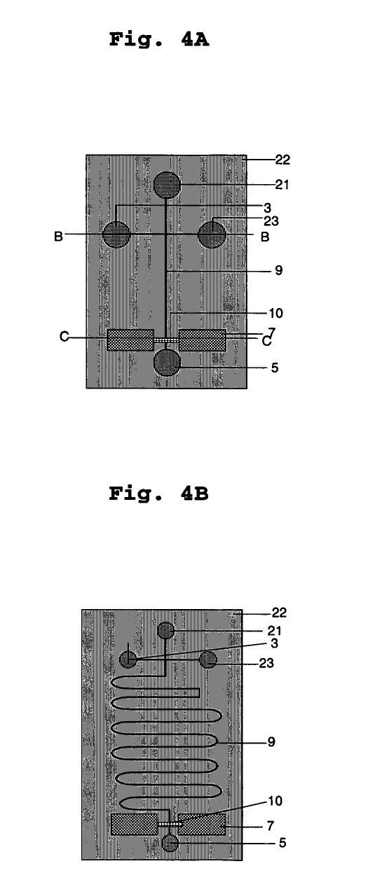

FIG. 4 shows top views of the sensor chip for lab on chip applications,

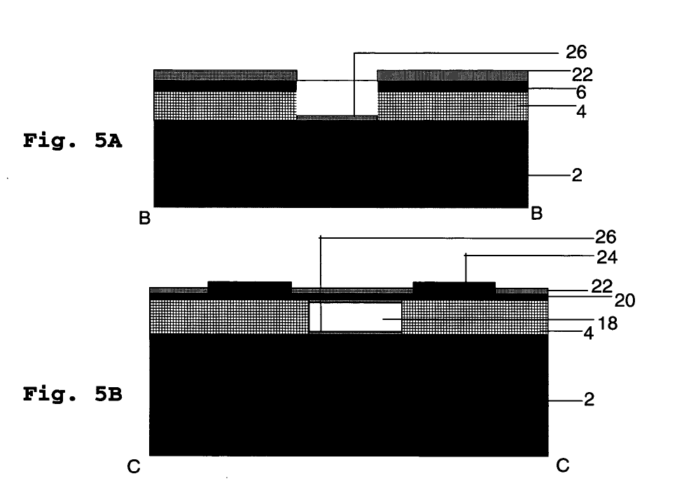

FIG. 5 shows a cross sectional view of the chip at the separation and detection regions,

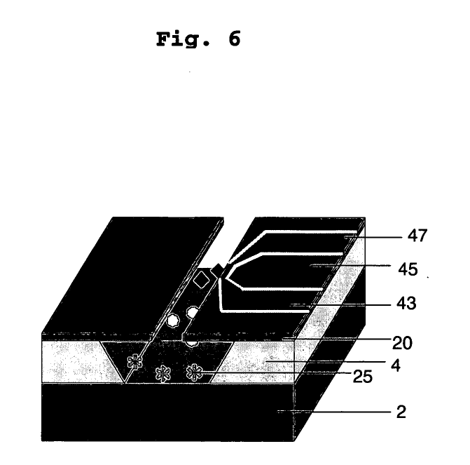

FIG. 6 shows integrated detector with tunable lateral transistor,

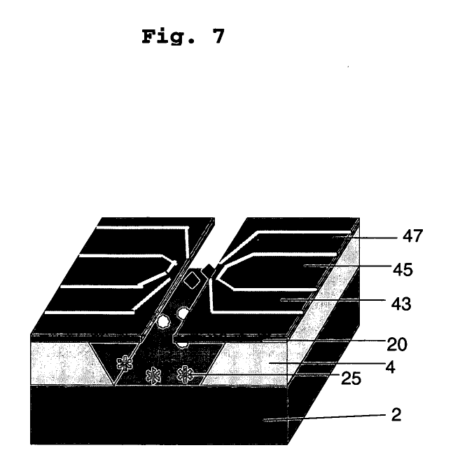

FIG. 7 shows integrated detector with tunable lateral transistor on both sides of the microchannel,

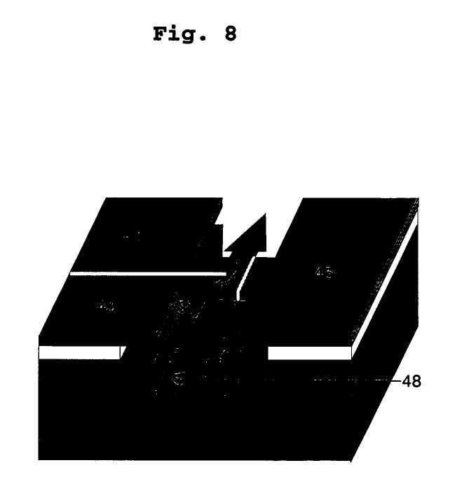

FIG. 8 shows the entropic based separation of DAN,

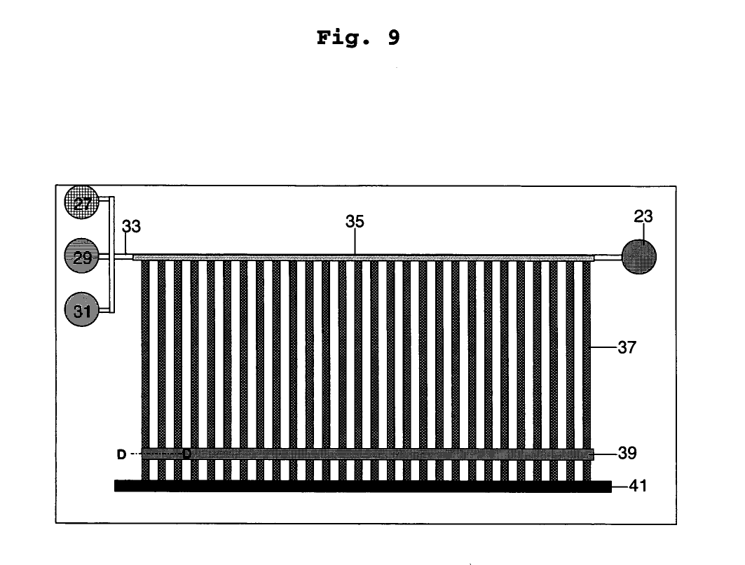

FIG. 9 shows top view of a sensor based protein chip,

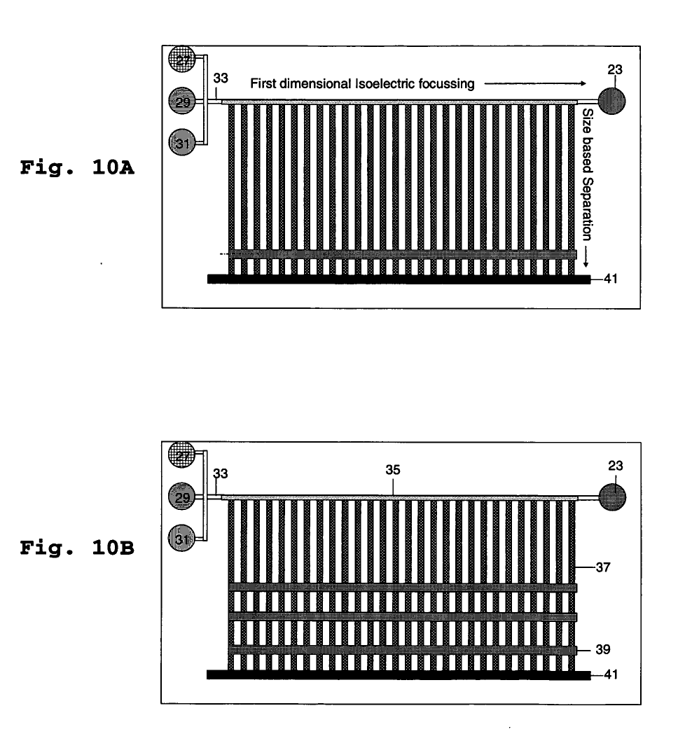

FIG. 10a & b shows working and multi-detection on protein chip,

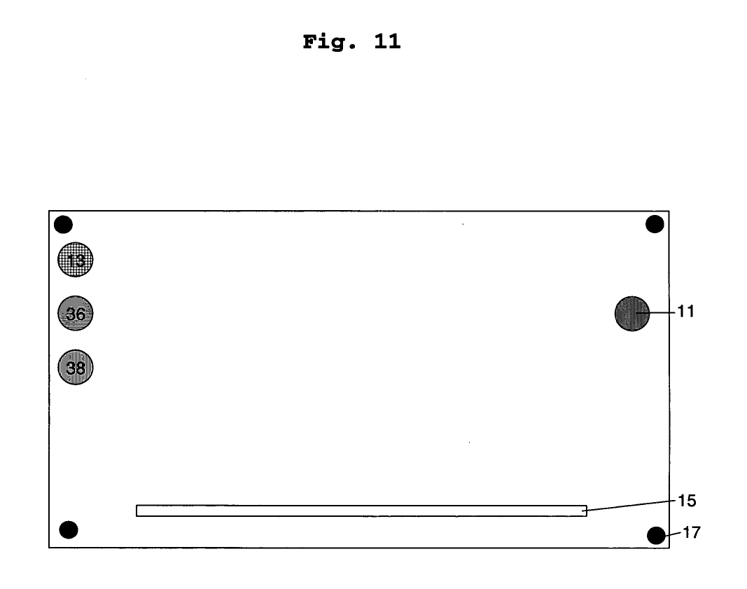

FIG. 11 shows the cover plate for the protein chip,

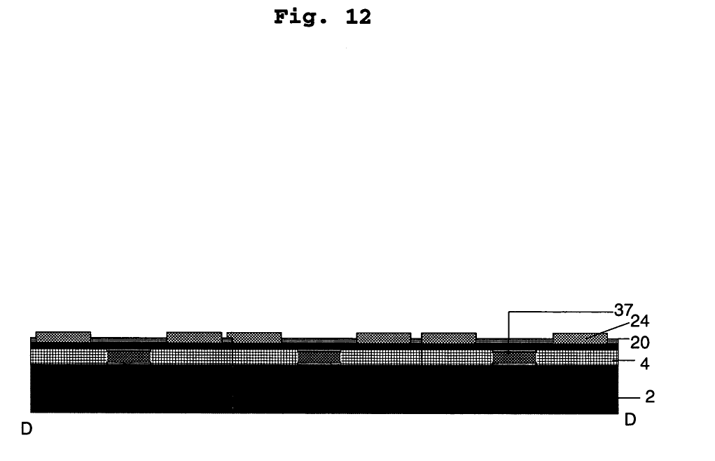

FIG. 12 shows the cross sectional view of the protein chip with three branch channels visible,

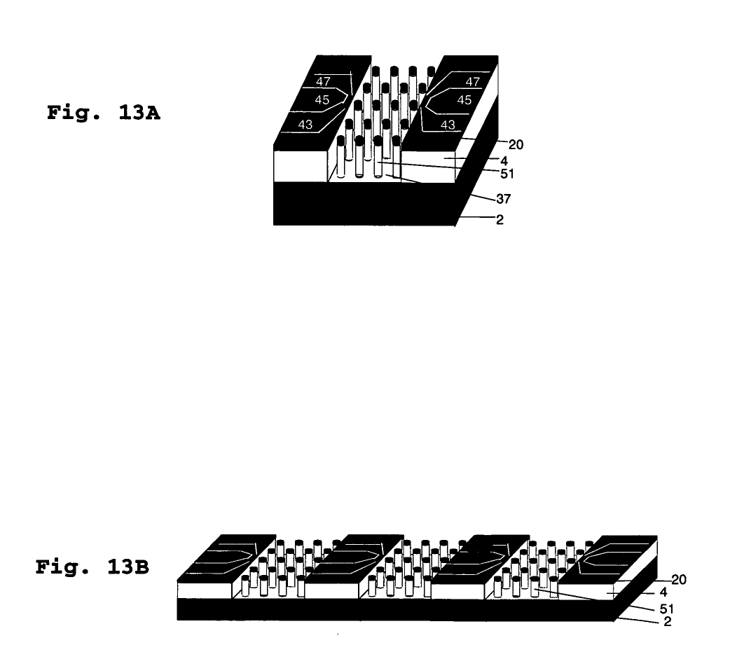

FIG. 13 shows a pillar like physical structures for size base separation,

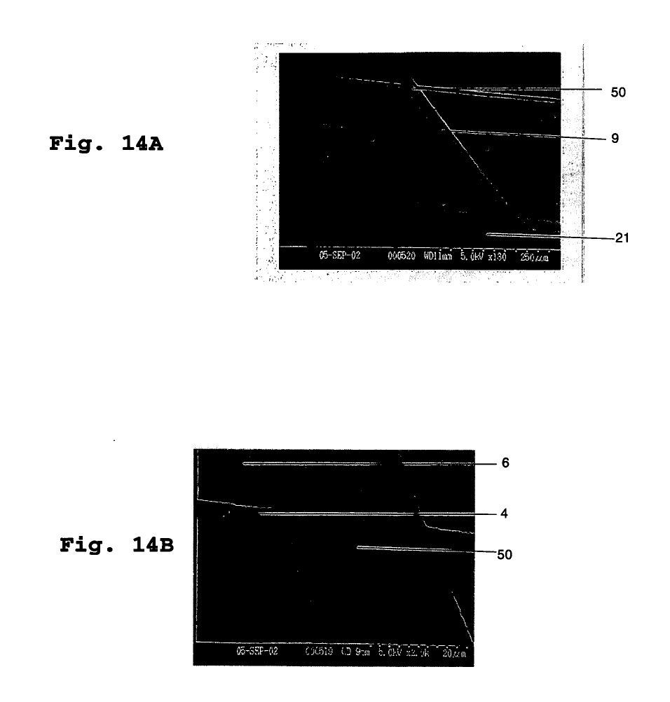

FIG. 14 shows SEM pictures of the micro-fabricated structure,

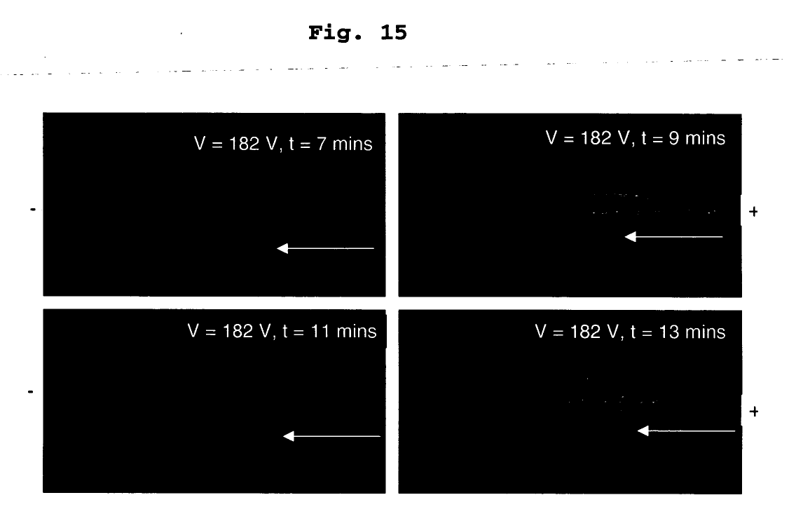

FIG. 15 shows pictures used to explain electro-osmotic pumping,

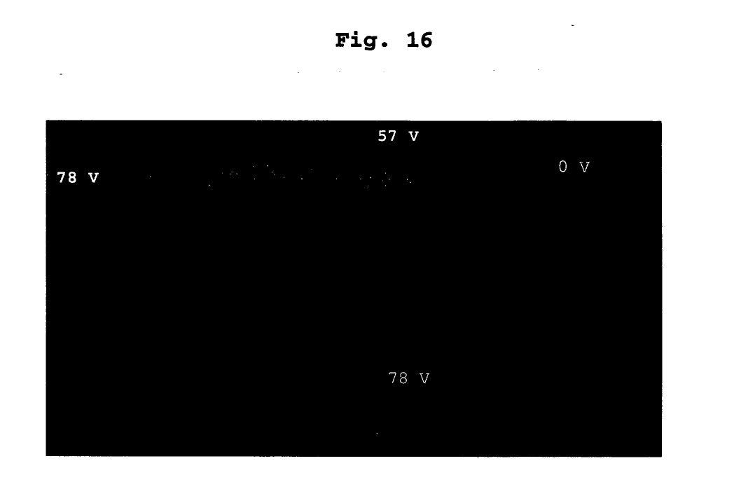

FIG. 16 show a picture used for explaining the pinching injection mode,

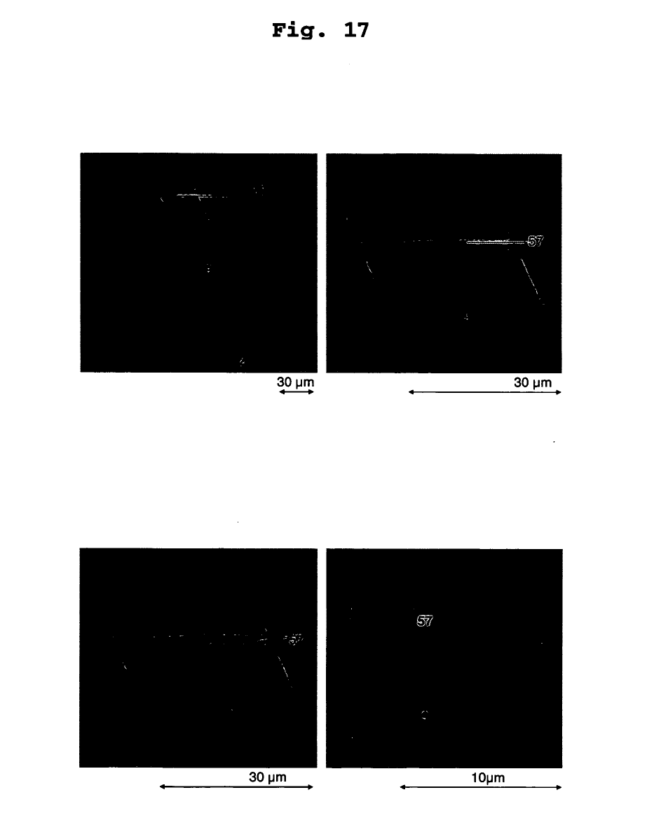

FIG. 17 show SEM pictures of realized bridge structures for detection,

The invention will now be described by way of example and with reference to the accompanying drawings in which:

Like components bear the same reference signs.

FIG. 1 shows the multi-layered silicon on insulator substrate. 2 is the bulk silicon layer with dimensions between 400 and 800 microns. 4 represents the buried oxide or the box oxide layer with thickness between 50 nm to 20 microns. 6 represents the top silicon layer with thickness between 50 nm to 400 nm. 8 represents the natural oxide layer.

FIG. 2 shows the schematic of a local sensor cover plate and the sensor chip. In the chip, 1 represents the chip as a whole, 3 represents the sample reservoir, 5 represents the waste reservoir, 7 represents the metallic contacts, 9 represents the microchannel, 10 represents the top silicon layer doped with charge carriers. In the cover plate, 11 represents the access hole to the waste reservoir, 13 represents the access hole to the sample waste reservoir, 15 represents grooves for metallic contacts, 17 represents holes for screws

FIG. 3 shows the cross sectional view of the sensing chip at the transistor region. In the cross sectional view 2 represents the bulk silicon layer, 4 represents the box oxide layer, 18 represents the microchannel, 20 represents the top silicon layer doped with charge carriers 22 represents the passivation layer, 24 represents the deposited metallic contacts, 26 represents the passivated layer on the bulk silicon layer.

FIGS. 4A and 4B show the top view of the sensor Chip for Lab on Chip applications. 5 represents the waste reservoir, 7 represents the metallic contacts, 10 represents the top silicon layer doped with charge carriers, 9 represents the microchannel, 23 represents the sample waste reservoir, 3 represents the sample reservoir, 21 represents the buffer reservoir, 22 represents the passivation layer.

It is to be noted that the invention is not limited to the described single embodiments but rather covers combined features of them.

FIG. 5A shows the cross sectional views along the line B-B of FIG. 4 at the injection region and FIG. 5B shows the cross sectional views along the line C-C at the detection region of FIG. 4A. 2 represents the bulk silicon layer, 4 represents the box oxide layer, 6 represents the top silicon layer, 18 represents the microchannel, 20 represents the top silicon layer doped with charge carriers, 22 represents the passivation layer, 24 represents the deposited metallic contact, 26 represents the passivated layer on the bulk silicon layer.

FIG. 6 shows scheme for integrated detectors with a tunable lateral transistor. 2 represents the bulk silicon layer, 25 represents the analytes, 4 represents the box oxide layer, 20 represents the top silicon layer doped with charge carriers, 43 represents source, 45 represents an auxiliary gate, 47 represents drain. According to the invention the analyte is used as the gate of the FET. With the auxiliary gate electrode 45 the transistor channel can be biased in order to shift the working region of the transistor, as required.

FIG. 7 shows a similar lateral transistor but with the transistors integrated on both sides of the microchannel. The legends are the same as in FIG. 6.

FIG. 8 shows the entropic based separation of DNA by a sensor chip. 43 represents the source, 45 represents a gate, 47 represents drain and 48 represents the DNA molecules.

FIG. 9 shows the top view of a sensor based protein chip. 41 represents the waste trench, 39 represents the FET detection region, 37 represents microchannel with sieving matrix, 35 represents microchannel with pI gradient matrix, 23 represents sample waste reservoir, 33 represents microchannel, 27 represents the sample reservoir in the protein chip, 29 represents matrix reservoir for the 1st dimensional separation, 31 represents the equilibration reservoir.

FIGS. 10A and 10B show the working and multi-detection on the protein chip. The figures depicts the functions of the channels. The legends are similar to the ones used above in FIG. 8.

FIG. 11 shows the cover plate for the protein chip. 13 represents the access hole for the sample reservoir, 36 represents access hole on cover plate for the introduction of pI gradient medium, 38 represents access hole on cover plate for the introduction of equilibration medium, 11 represents access hole for waste reservoir , 15 represents an access slit for metal contacts, 17 represents screw positions.

FIG. 12 shows the cross sectional view of the protein chip showing just the first three channels. 2 represents the bulk silicon layer, 4 represents the box oxide layer, 20 represents the top silicon layer doped with charge carriers, 24 represents the metallic contacts, 37 represents the microchannel with sieving matrix.

FIG. 13A shows a protein chip with the pillar like physical structures as matrix for performing sieving or size based separation. 37 represents the microchannel, 51 represents the pillar like structures for size based separation while the other legends represent the same as mentioned for FIGS. 10 and 1 FIG. 13B shows the lateral view of the protein chip showing the first three channels with pillar like structures. The legends for the picture are the same as described above in FIG. 12.

FIG. 14A and 14B show Scanning Electron Microscopy (SEM) pictures of fabricate micro-device. The micro-channels are 30 μm wide and 3 μm deep while the reservoirs are 1 mm in diameter and 3 μm deep. 50 represents the intersection of the micro-channels, 9 represents microchannel, 21 represents the buffer reservoir.

FIG. 15 shows the electro-osmotic pumping of Rhodamine dye.

FIG. 16 shows the pinching injection mode observed for introduction of a plug of Rhodamine to the separation channel.

FIG. 17 shows SEM pictures of the realized bridge like structures as transistors for transduction of the charge passing underneath. 57 represents the bridge like structure on the microchannel, 9 represents the microchannel, 21 represents the reservoir.

### Fabrication of the Device

Local Sensor

The proposed invention consists essentially of a sensor microchip resting on a mount (preferably made up Teflon) and covered by a cover plate (made by polymeric substance such as PDMS, PMMA or Polyimide). The sensor chip consists of two main reservoirs a sample reservoir and a waste reservoir connected by a microchannel. The analyte(s) of interest are manipulated by pumping or by electrokinetic means, towards the waste reservoir and the FETs incorporated sense the charged analytes passing by.

Fabrication of structures: The reservoir and micro-channels are fabricated by photolithography and wet or dry etching techniques. The photolithography steps are used to transfer structures from a Chromium mask onto the sensor chip. In the wet etching technique, in the first step the top Silicon layer is removed by a mixture of HNO3 (69% ) and HF (1.5%) in the ratio 70:30 and in the next step the photoresist is removed and the silicon dioxide layer (box oxide layer) is etched using 5% HF, known to be very selective against silicon oxide. The chip may be passivated or not passivated depending on the mode used for manipulation of analyte sample.

In case a pump is used, no passivation is required. If an electrokinetic mode is used for sample manipulation then passivation is desirable as silicon has a low breakdown potential, a passivated layer thick of 200 nm of dry silicon oxide gives good passivation and the structure is able to withstand electric field strengths of the order of 440 V/cm or even more as has already been witnessed by us.

The detection of the analytes of interest is performed by the Field effect transistors which are monolithically integrated on the same platform. The FETs could be seated on freely suspended bridges over the micro-channels (FIG. 3) or may be fabricated on the one (FIG. 6) or both of the top silicon layers (FIG. 7) overhanging the underetched channels.

### Fabrication of Detector—In-Plane-Gate Field Effect Transistors

Charge carriers can be introduced into a previously undoped top silicon layer by either diffusion doping (Spin-on-dopant and annealing), or by ion-implantation of the substrate before sample processing (entire wafer) or by operating the device with a back-gate voltage accumulating carriers in an inverted MOSFET (Metal-oxide-semiconductor FET) mode. The latter mode operation of operation works only for non-underetched FET structures. Alternatively, the top Si layer may be epitaxially overgrown with a doped Si layer by using, e.g., molecular beam epitaxy (MBE). FET structures are fabricated out of this layer either by using standard photolithographic techniques as described above for lateral dimensions down to ˜1 μm. To achieve enhanced spatial resolution and enhanced sensitivity in the case of In-Plane-Gate (IPG) FET operation, i.e., with typical structure sizes down to 30-100 nm, high resolution lithographic techniques have to be employed in combination with selective doping or dry etching techniques. These can comprise of electron beam lithography for resist etch mask patterning, ion implantation or diffusion for masked doping and plasma etching such as reactive ion etching (RIE). Alternatively, IPG-FETs structures can be directly written by focused ion beam (FIB) or by focus laser beam oxidation (R. A. Deutschmann, M. Huber et al., Microelectronic Engineering 48 (1999) 367-370) into overhanging Si structures. After micro- and sub-micron-fabrication the structures are passivated by growing 200 nm of dry oxide. For obtaining the source and drain regions, photolithography is again used to remove the oxide layer (passivated layer) after which the source and drain regions are defined by metal deposition (TiAu). In a bridge-like support for the IPG-FET detectors, the source and drain are formed on the two ends of the bridge. The bridge is passivated above and below with Silicon dioxide and this region forms the gate region.

Sensor Based Lab on Chip Device:

Fabrication: The fabrication of this device is done by steps similar to the ones described in the sensor section, the design of the Chromium mask is modified according to the requirement.

Sensor Based Protein Chip Device:

Fabrication: The fabrication of this device is done by steps similar to the ones described in the sensor section, the design of the Chromium mask is modified according to the requirement.

### Working of the Devices

1. Local Sensor:

Working: The analyte would be introduced in the reservoirs and then manipulated from the sample reservoir towards the waste reservoir. As the charged analytes pass underneath the bridge coming in contact with the surface, a change in surface potential would be observed leading to change in the band structure and thus charge distribution of the silicon material changing its conductivity, which is measured as electrical signal. IPG FETs allow the fine tuning of their sensitivity to surface potential changes by adjusting the electrical width of the transistor channel (i.e., its working point) through the in-plane electric fields. Using LabView or other interface program the protocols are run in an automated format.

2. Sensor Based Lab on Chip Device:

Working: The sample comprising several analytes is introduced in the sample reservoir and the sample is mobilized electrokinetically towards the sample waste reservoir. Buffer solution from the buffer reservoir is driven in perpendicular direction so that a fine plug of the sample is introduced into the longer microchannel section which facilitates separation of the individual analytes based on the differential electrophoretic mobility. The analyte bands passing by are sensed by the Field effect Transistors seated on the same platform and detected in manner similar to that described before in Section

The microstructures on such sensor based chips could be simple intersection channels terminating into reservoirs shown in FIG. 4A or maybe several channels spirally coiled to facilitate longer separation length for a given area as shown in FIG. 4B. Similarly the detectors maybe seated or localized in bridge like structure (FIGS. 4 and 5) or several bridge like structures or on silicon structures overhanging the micro-channels as shown in FIGS. 6 and 7.

Besides, other detection techniques such as Optical detection, mass spectrometry can be coupled to the sensor chip, in this case the sensor based chip just acts as a platform for pre-reactions such as derivatization, injection and separation and other related manual techniques.

Various parameters associated with injection (such as the potential parameters), separation (such as the separation potential and buffer conditions) and detection are optimized and tailor made for specific analyte matrices. Besides, using programming and interface software the device is automated according to the application.

3. Sensor Based Protein Chip Device:

Working: The protein mixture are prepared in a buffer solution and introduced into the sample reservoir (27 in FIG. 8). The matrix (carrier ampholytes or immobilines) for the first dimensional separation based on the isoelectric points is introduced in another reservoir (29 in FIG. 8). In the first step the first dimensional separation channel (35 in FIG. 8) is filled with the isoelectric focussing matrix and the pH gradient formation facilitated. The proteins are then introduced into this channel by electrokinetic means and allowed to focus themselves on the basis of their isoelectric points (pI values). This ensures the separation of proteins on the basis of their isoelectric point. Counter potentials are applied in the second dimension channels in a direction against the first dimensional channels to ensure no bleeding of the protein sample into the second dimensional channel occurs during the first dimensional separation. Proteins separated in the first dimension are then subjected to second dimensional size based separation (FIG. 9a).

The proteins separated in the first dimension on the basis of their isoelectric points are rinsed electro-kinetically with a surfactant such as sodium dodecylsulphate (SDS) solution so that equal charge are incorporated on all proteins leaving the size factor as the major separating factor. The SDS treated proteins are then electro-kinetically moved in perpendicular direction. The moving proteins are assorted by the sieving matrix in the second dimensional channels (37 in FIG. 8) which may be a gel or physical pillar like structures (FIG. 12, 13). The proteins carrying negative charge are detected by the Field effect transistors seated in the same platform in bridge like (FIGS. 8,9,11) or other format (12, 13). The protocol procedures once optimized are then performed in an automated format using special interface programs like Lab View.

Simulations on electrophoretic migration of proteins through a given matrix would enable correlate the migration speeds with the molecular mass and thus identifying the protein.

The chip according to the present invention can be used for analyzing a wide range of samples, e.g. biochemical, environmental, clinical or forensic samples.

1: On-chip integrated detector for analyzing fluids, comprising
insulating material partly enclosing a cavity for accommodating an analyte, said cavity being defined at the bottom and at least partly at its sides by said insulating material,
and a gateless field effect transistor (FET) formed in a distance from the bottom of the cavity, the sensing surface of which is facing the analyte.

2: On-chip integrated detector for analyzing fluids, according to claim 1, characterized in that the cavity is formed as a channel.

3: On-chip integrated detector for analyzing fluids according to claim 1, characterized in that an opening of the cavity is substantially opposed to the bottom side.

4: On-chip integrated detector for analyzing fluids according to claim 1, characterized in that the material defining the bottom of the cavity consists of Si having a passivation layer on it.

5: On-chip integrated detector for analyzing fluids according to claim 1, characterized in that the material defining the bottom side of the cavity and the buried layer material defining further part of the cavity consist of SiO₂.

6: On-chip integrated detector for analyzing fluids according to claim 1, characterized in that the FET is formed in a flat layer.

7: On-chip integrated detector for analyzing fluids according to claim 1, characterized in that the FET region is isolated from the rest of the substrate by means of insulation boundaries.

8: On-chip integrated detector for analyzing fluids according to claim 3, characterized in that one or plural FETs partly extend over the opening of the cavity.

9: On-chip integrated detector for analyzing fluids according to claim 3, characterized in that one or plural FETs bridge the opening.

10: On-chip integrated detector for analyzing fluids according to claim 9, characterized in that the sensing area(s) of the channel(s) of the FET Bridge the opening.

11: On-chip integrated detector for analyzing fluids according to claim 9, characterized in that a gate electrode is provided for biasing the gate of the FET the gate of the FET bridges the opening.

12: On-chip integrated detector for analyzing fluids according to claim 1, characterized in a thin passivating layer is sputtered on the sensing area(s) of the FET(s).

13: On-chip integrated detector for analyzing fluids according to claim 2, characterized in that the channel like cavity has an inlet opening and an outlet opening.

14: On-chip integrated detector for analyzing fluids according to claim 2, characterized in that inlet opening of and/or channels or channels of the biosensor are deliberately constructed to enhance turbulent flows.

15: On-chip integrated detector for analyzing fluids according to claim 2, characterized in that the channel like cavity has a main or inlet reservoir and a waste reservoir.

16: On-chip integrated detector for analyzing fluids according to claim 2, characterized in that a removable cover plate is provided for covering the open part of the channel like cavity.

17: On-chip integrated detector for analyzing fluids according to claim 16, characterized in that the removable cover plate has openings for accessing the main reservoir and the waste reservoir.

18: On-chip integrated detector for analyzing fluids according to claim 16, characterized in that the cover plate is made of a polymeric substance.

19: On-chip integrated detector for analyzing fluids according to claim 10, characterized in that the channel like cavity has a meander like form.

20: On-chip integrated detector for analyzing fluids according to claim 2, characterized in that pumping means are provided for conveying analyte from the main reservoir to the waste reservoir.

21: On-chip integrated detector for analyzing fluids according to claim 2, characterized in that electrokinetic means are provided for conveying analyte through the channel like cavity.

22: On-chip integrated detector for analyzing fluids according to claim 21, characterized in that electrokinetic means comprise an electrical means for applying a voltage across part or all the length of the channel like cavity.

23: On-chip integrated detector for analyzing fluids according to claim 2, characterized by a second channel like cavity oriented substantially perpendicular to the main channel like cavity and communicating with it at a crossing point.

24: On-chip integrated detector for analyzing fluids according to claim 23, characterized in that each channel like cavity communicates with a main or inlet reservoir and with a waste reservoir.

25: On-chip integrated detector for analyzing fluids according to claim 24, characterized in that the main reservoir of one of the channel like cavities is provided for letting in the analyte and the other main reservoir is provided for letting in a buffer solution.

26: On-chip integrated detector for analyzing fluids according to claim 23, characterized in that additionally a gate electrode is provided for biasing the channel of the FET.

27: On-chip integrated detector for analyzing fluids according to claim 2, characterized by one main channel like cavity from which a number of branch channels is branched off and by at least one means for measuring the electric charge of the fluid in a region of each branch channel in a distance from the main channel like cavity.

28: On-chip integrated detector for analyzing fluids according to claim 27 characterized in that there are electrical means for variably applying a bias voltage across the length or part of the length of the branch channels.

29: On-chip integrated detector for analyzing fluids according to claim 28 characterized in that the electrical means can bias the branch channels to prevent movement of the fluids from the main channel like cavity into the branch channels.

30: On-chip integrated detector for analyzing fluids according to claim 28 characterized in that the electrical means can bias the branch channels to promote movement of the fluids from the main channel like cavity to the distant end of the branch channels.

31: On-chip integrated detector for analyzing fluids according to claim 27, characterized in that the measuring means are FETs.

32: On-chip integrated detector for analyzing fluids according to claim 31, characterized in that the FETS are crossing the branch channels.

33: On-chip integrated detector for analyzing fluids according to claim 32, characterized in that the channels of the FETs are bridging the branch channels.

34: On-chip integrated detector for analyzing fluids according to claim 27, characterized in that there are plural measuring means at each branch channel.

35: On-chip integrated detector according to claim 1, for analyzing macromolecules like proteins where pillar like structures act as physical sieves performing size based separation.

36: On-chip integrated detector for analyzing macromolecules like DNA where the chip has thin and thick regions for the entropy based separation.

37: On-chip integrated detector where a micro fluidic component and a detector are integrated on the same platform and the detection principle is based on the field effect phenomenon.

38: On-chip integrated detector where in the outlay facilitates separation of proteins in two dimensions, isoelectric focusing based separation as the first and size based separation as the second, followed by the subsequent detection by the detectors integrated in the same platform.
